(19) United States
(12) Patent Application Publication
(10) Pub. No.: US 2013/0009143 A1
(43) Pub. Date: Jan. 10, 2013

(54) PHOTO SENSOR AND METHOD OF FABRICATING THE SAME

(76) Inventors: Chih Chen, Hsinchu City (TW); Chien-Min Liu, Taichung City (TW); Yuan-Chieh Tseng, Hsinchu City (TW)

(21) Appl. No.: 13/253,656

(22) Filed: Oct. 5, 2011

(30) Foreign Application Priority Data
Jul. 7, 2011 (TW) 100124002

(51) Int. Cl. H01L 31/0264; H01L 31/18

(52) U.S. Cl. 257/43; 438/92; 257/E31.004; 257/E31.126

(57) ABSTRACT

A photo sensor and a method of fabricating the same are disclosed, the photo sensor of the present invention has ultra-high Schottky junction area per unit volume, and the photo sensor comprises: a first conductive layer; plural metallic nanowires, in which one end of each metallic nanowire connects with the first conductive layer and is covered with a semiconductive layer having a width of 1 nm to 20 nm; and a second conductive layer locating opposite to the first conductive layer, whereby the plural metallic nanowires locate between the first conductive layer and the second conductive layer, and the semiconductive layer contacts with the second conductive layer, wherein the photo sensor of the present invention is used to detect ultra violet (UV) light with a wavelength of 10 nm-400 nm.

### CROSS REFERENCE TO RELATED APPLICATION

This application claims the benefits of the Taiwan Patent Application Serial Number 100124002, filed on Jul. 7, 2011, the subject matter of which is incorporated herein by reference.

### BACKGROUND OF THE INVENTION

1. Field of the Invention

The present invention relates to a photo sensor and a method of fabricating the same and, more particularly, to a photo sensor having a core-shell structure with large Schottky contact area and being capable for use in UV detection and a method of fabricating the same.

2. Description of Related Art

In recent years, the demand for photo sensors has been largely increased. With the miniaturization of electronics, the design trend of photo sensors is towards high sensitivity and small size.

As well known to those skilled in the art, photo sensors are usually designed to have a nanowire with Ohmic contact on both ends/sides thereof. In recent years, there has been developed a structure that comprises nanowires with Schottky contact on one side and Ohmic contact on the other side, which has higher photosensitivity compared with those which have Ohmic contact on both sides of the nanowires. However, in both photo sensors with Ohmic contact on both sides or photo sensors with Schottky contact on one side and Ohmic contact on the other side, a bias voltage is needed while those photo sensors are used, which is energy-requiring and unsatisfactory for energy conservation. Therefore, it is a present need to develop photo sensors that can work without a bias voltage.

In the Taiwan Patent No. I 322509, a silicon-based photo-detector and a method for providing the same are disclosed, which forms the photo-detector by (a) preparing a silicon substrate; (b) forming a patterned mesa in the silicon substrate; and (c) forming a patterned conductive layer over the patterned mesa. However, the manufacturing process is complex, and an external bias voltage is still needed when the photo-detector is used.

T. Zhai et al. has disclosed a method which utilizes a thermal evaporation method for growing indium selenide (In₂Se₃) nanowires array, and then spreads single indium selenide nanowire on the substrate followed by electron-beam lithography to define two Ohmic contact electrodes to give a photo-detector (T. Zhai, X. Fang, M. Liao, X. Xu, L. Li. B. Liu, Y. Koide, Y. Ma, J. Yao, Y. Bando and D. Golberg ACS Nano 4, 1596 (2010)). However, the process of thermal evaporation is time-consuming, and the steps for electron-beam lithography to define the electrodes are complex and also expensive equipment is required. Furthermore, the provided photo-detector still needs a bias voltage while being used.

In 2010, Sachindra Nath Das et al. in doing research about the UV detection efficiency of single ZnO nanowire, discovered that single ZnO nanowire has low-power UV detection ability (S. N. Das, K. J. Moon, J. P. Kar, J. H. Choi, J. Xiong, T. Lee and J. M. Myoung Appl. Phys. Lett 97, 022103 (2010)). Sachindra Nath Das et al. studied the structure having one point Schottky contact on one side and one Ohmic contact on the other side, but the result shows that this structure still needs a bias voltage while being used, which means a non-power UV detection ability is not achieved.

Therefore, it is desirable to provide an improved photo-detector, which is able to achieve non-power UV detection for the energy-saving criteria needs, and simultaneously has high photosensitivity.

### SUMMARY OF THE INVENTION

Therefore, the present invention provides a photo sensor, which comprises: a first conductive layer; plural metallic nanowires, in which one end of each metallic nanowire connects with the first conductive layer, and each of the metallic nanowires are covered with a semiconductive layer having a thickness of 1 nm-20 nm; and a second conductive layer located opposite to the first conductive layer, whereby the plural metallic nanowires locate between the first conductive layer and the second conductive layer, and the semiconductive layer contacts with the second conductive layer, wherein the photo sensor is used to detect ultra violet (UV) light with a wavelength of 10 nm to 400 nm.

The photo sensor of the present invention has a core-shell array structure (metallic nanowire as core, and semiconductive layer as shell) that generates a large Schottky contact area, and therefore no external bias voltage is needed while the photo sensor is used for photo sensing. The photo sensor of the present invention has a high photosensitivity, and the structure of the one-dimensional nanowire may contribute to confine the carrier transportation direction, whereby the transportation efficiency of the electrical current can be increased. Consequently, the present invention provides a photo sensor structure for photo sensor devices with the advantages of low power, high sensitivity, and high response speed, which can be used in photo switches for commercial, military, or space exploration applications. According to the photo sensor structure of a conventional technique, usually both of the connecting points at the opposite sides of the nanowire are Ohmic contacts, which needs bias voltage during operation. Although some studies propose a structure in which one Ohmic contact is changed into one Schottky contact, a bias voltage is still needed during photo sensing. In contrast, the photo sensor of the present invention has a core-shell array structure that generates an extremely large Schottky contact area, and therefore external bias voltage is no longer needed (the dark current is zero) while the photo sensor is used for photo sensing. Also, the photo sensor of the present invention has a high sensitivity for UV lights without bias voltage.

According to the photo sensor of the present invention, the plural metallic nanowires are preferably arranged in an array.

According to the photo sensor of the present invention, the plural metallic nanowires are preferably arranged vertically to the first conductive layer.

According to the photo sensor of the present invention, the metallic nanowire and the semiconductive layer preferably together form a core-shell structure.

According to the photo sensor of the present invention, preferably a Schottky contact is formed by the contact between the metallic nanowires and the semiconductive layer.

According to the photo sensor of the present invention, the metallic nanowire preferably has an average diameter of 60 nm to 70 nm.

According to the photo sensor of the present invention, the metallic nanowire is preferably made of: nickel, zinc, or mixtures thereof.

According to the photo sensor of the present invention, the semiconductive layer is preferably made of nickel oxide, zinc oxide, titanium oxide, or mixtures thereof.

According to the photo sensor of the present invention, the materials of the metallic nanowires and the semiconductive layer are preferably selected to ensure that a Schottky contact is formed between the metallic nanowires and the semiconductive layer.

According to the photo sensor of the present invention, the second conductive layer can be made of any electrically conductive transparent material such as indium tin oxide (ITO), aluminum doped zinc oxide (AZO), indium zinc oxide (IZO), or mixtures thereof.

The present invention also provides a method of providing a photo sensor, comprising: (A) providing a substrate; (B) forming a first conductive layer on the substrate; (C) forming plural metallic nanowires on the first conductive layer, in which one end of each metallic nanowire connects with the first conductive layer; (D) forming a semiconductive layer covering each of the metallic nanowires, in which the thickness of the semiconductive layer is 1 nm to 20 nm; and (E) forming a second conductive layer contacting with the semiconductive layer, in which the plural metallic nanowires locate between the first conductive layer and the second conductive layer; wherein the photo sensor is used to detect ultra violet (UV) light with a wavelength of 10 nm to 400 nm.

The photo sensor made by the present invention has a core-shell array structure that generates a large-area Schottky contact, and therefore no external bias voltage is needed while the photo sensor is used for photo sensing. The photo sensor of the present invention has a high photosensitivity for UV lights without bias voltage, which enables energy-free (non-power) UV detection and satisfies the requirements for energy-saving criteria.

According to the method of providing a photo sensor of the present invention, wherein in the step (C), the plural metallic nanowires are preferably formed by steps (C1): forming an aluminum anode oxide (AAO) layer comprising plural holes on the first conductive layer; (C2) forming metallic nanowires in the holes of the AAO layer; and (C3) removing the AAO layer. The method for forming an aluminum anode oxide layer is so called an anodization (or anode oxidation) method.

According to the method of providing a photo sensor of the present invention, wherein in the step (C2), the metallic nanowires can be formed in the holes of the AAO layer preferably by electroplating or electroless plating. The method of the present invention combines a technique of anodization (or anode oxidation) and a technique of electroless plating so as to form a nanowires-array on the substrate first, followed by providing a simple oxidation treatment such as annealing or other surface treatment methods such as an atomic layer deposition (ALD) to obtain a core-shell structure with large-area Schottky contact, wherein those core-shell structures are well arranged in an array, and therefore a non-power UV detection photo sensor is achieved.

According to the method of providing a photo sensor of the present invention, the distance between the metallic nanowires is preferably 30 nm-40 nm.

According to the method of providing a photo sensor of the present invention, the metallic nanowires are preferably made by using AAO layer having regularly arranged holes, so as to achieve metallic nanowires that are regularly arranged. However, the method for forming the metallic nanowires is not limited thereto, a patterned silicon substrate having regularly arranged holes may also be used to form the metallic nanowires.

According to the method of providing a photo sensor of the present invention, wherein in the step (D), the semiconductive layer is preferably made by a step (D1): annealing the plural metallic nanowires to form a metal oxide-semiconductive layer on the metallic nanowires. Herein, the annealing process is preferably performed under an oxygen atmosphere in order to oxidize the metallic nanowires.

According to the method of providing a photo sensor of the present invention, wherein in the step (D), the time for the annealing is not specially limited, for example, the time for the annealing can be 10 minutes to 120 minutes, preferably 30 minutes. The annealing process is used to oxidize the surface of the metallic nanowires, thereby the time for the annealing should be properly controlled to obtain a desirable core-shell structure. If the time for the annealing is too long, the metallic nanowires may entirely turn into metal oxide whereas a core-shell structure cannot be achieved. If the time for the annealing is too short, the semiconductive layer is formed insufficiently so as the photo sensitivity of the photo sensor may be unsatisfactory.

According to the method of providing a photo sensor of the present invention, wherein in the step (D1), the temperature for the annealing can be, for example, 250° C. to 450° C., and preferable 300° C. The temperature of the annealing should be adjusted depending on the material of the metallic nanowires. The temperature of the annealing should enable the metallic nanowires to be oxidized but keep the metallic nanowires from melting. For example, when the metallic nanowires are made of zinc, the temperature of the annealing should be about 300° C. to 420° C., since the melting temperature of zinc is about 420° C.

According to the method of providing a photo sensor of the present invention, wherein in the step (D), the semiconductive layer is preferably formed by a step (D2): forming the semiconductive layer on each of the metallic nanowires by an atomic layer deposition (ALD) method. The atomic layer deposition method can increase the thickness uniformity of the semiconductive layer, and by the atomic layer deposition method, the thickness can be easily adjusted.

According to the method of providing a photo sensor of the present invention, wherein in the step (D), the substrate is preferably selected from the group consisted of: a silicon substrate, a glass substrate, a quartz substrate, a metallic substrate, a plastic substrate, a printed circuit board, and mixtures thereof.

According to the method of providing a photo sensor of the present invention, the materials of the metallic nanowire and the semiconductive layer are preferably selected to ensure that a Schottky contact is formed between the metallic nanowire and the semiconductive layer.

In the present invention, according to the needs, the length of the metallic nanowire can be adjusted by, for example, changing the thickness of the aluminum anode oxide layer or the time period of the electroplating or electroless plating.

Other objects, advantages, and novel features of the invention will become more apparent from the following detailed description when taken in conjunction with the accompanying drawings.

### BRIEF DESCRIPTION OF THE DRAWINGS

FIGS. 1A to 1E are manufacturing process of the photo sensor in a preferred example of the present invention;

FIG. 2 is a cross-sectional view along the X-X′ line in the FIG. 1E;

FIG. 3 is a UV light detecting test result of the testing example 1;

FIG. 4 is an energy band for the interface between the nickel and nickel oxide;

FIG. 5 is a UV light detecting test result of the testing example 2; and

FIG. 6 is an energy band for the interface between the nickel and titanium dioxide.

### DETAILED DESCRIPTION OF THE PREFERRED EMBODIMENT

### Example 1

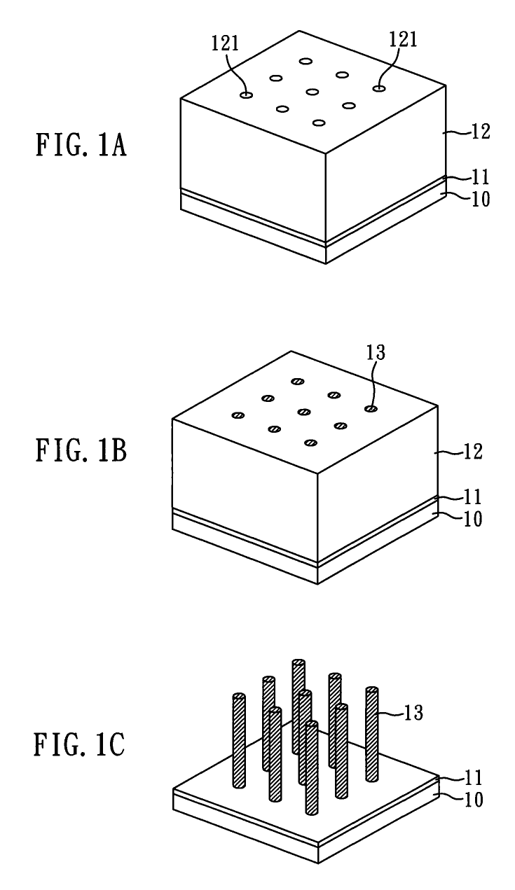

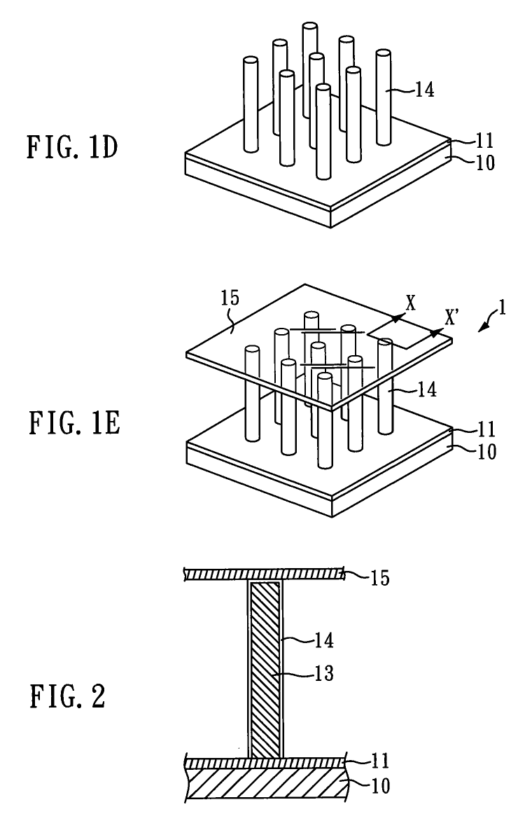

Reference with FIGS. 1A to 1E, first, a silicon substrate 10 is provided (as shown in FIG. 1A). Then, a first conductive layer 11 made of aluminum is formed on the silicon substrate 10, followed by forming an aluminum anode oxide (AAO) layer 12 on the first conductive layer 11. Herein, the aluminum anode oxide layer 12 has plural holes 121, and the thickness of the aluminum anode oxide layer 12 is about 300 nm. After that, nickel nanowires 13 are formed by electroless plating with an electroless plating solution (C. M. Liu, W. L. Liu, S. H. Hsieh, T. K. Tsai and W. J. Chen Appli Surf. Sci 243, 259 (2005)) in each hole 121 of the aluminum anode oxide layer 12, as shown in FIG. 1B. Herein, the average length of the nickel nanowires 13 is 300 nm, and the average diameter of the nickel nanowires 13 is 70 nm. According to the needs, the length of the nickel nanowires 13 can be adjusted by, for example, changing the thickness of the aluminum anode oxide layer 12 or changing the time period of the electroless plating.

After electroless plating, the silicon substrate 10, with the nickel nanowires 13 and the AAO layer 12 thereon, is dipped in a sodium hydroxide (NaOH) solution for 35 minutes to remove the AAO layer 12, whereas the nickel nanowires 13 remain on the silicon substrate 10, as shown in FIG. 1C.

Then, the nickel nanowires 13 are oxidized on the surface by an annealing method to form a nickel oxide semiconductive layer 14 on the surface of the nickel nanowires 13 as shown in FIG. 1D, in which the semiconductive layer 14 has a thickness of about 5 nm. Therefore, a core-shell structure of nickel-nickel oxide is provided, and a Schottky contact is formed between the nickel nanowires 13 and the nickel oxide semiconductive layer 14. Herein, the temperature for the annealing is 300° C., and the time is 30 minutes.

Finally, an indium tin oxide (ITO) transparent layer 15 is formed on the nickel nanowires 13 and the nickel oxide semiconductive layer 14, and therefore the photo sensor of the present invention is obtained, as shown in FIG. 1E. Herein, the transparent layer 15 is formed by sputtering, and the indium tin oxide can be selectively replaced by aluminum doped zinc oxide (AZO), indium zinc oxide (IZO), or the like, as long as the material that is used is transparent and is electrically conductive.

Reference with FIGS. 1E and 2, in which the FIG. 2 is a cross-sectional view along the X-X′ line in the FIG. 1E, the photo sensor 1 of the present example comprises: a silicon substrate 10; a first conductive layer 11; plural metallic nanowires 13, in which one end of each metallic nanowire 13 connects with the first conductive layer 11, and each of the metallic nanowires 13 are covered with a semiconductive layer 14 having a thickness of about 1 nm to 20 nm; and an ITO transparent layer 15 (i.e. the second conductive layer) locating opposite to the first conductive layer 11, whereby plural metallic nanowires 13 locate between the first conductive layer 11 and the transparent layer 15, and the semiconductive layer 14 contacts with the transparent layer 15, wherein the photo sensor 1 is used to detect ultra violet (UV) light with a wavelength of 10 nm to 400 nm. In the photo sensor 1 of the present example, a Schottky contact is formed between the nickel nanowires 13 and the nickel oxide semiconductive layer 14.

In the photo sensor 1 of the present example, the silicon substrate 10 can be selectively replaced by a glass substrate, a quartz substrate, a metallic substrate, a plastic substrate, a printed circuit board, or the like, depending on demands.

The present example combines the technique of anodization (or anode oxidation) and the technique of electroless plating so as to form a nanowires-array on the substrate first, followed by providing a simple oxidation treatment (i.e. annealing) to obtain a core-shell structure with large Schottky contact area, wherein those core-shell (nickel-nickel oxide) structures are well arranged in an array, and therefore a non-power UV detection photo sensor is achieved, which has high UV sensitivity and satisfies the demand for energy conservation.

### Example 2

First, as shown in FIGS. 1A to 1C, plural nickel nanowires 13 are formed on the first conductive layer 11. Then, a titanium dioxide (TiO₂) semiconductive layer 14 is formed on each of the nanowires 13 by an atomic layer deposition (ALD) method, as shown in FIG. 1D.

Afterwards, an indium tin oxide (ITO) transparent layer 15 is formed on and contacting with the nickel oxide semiconductive layer 14, and therefore the photo sensor 1 of the present invention is obtained.

### Example 3

As above except that zinc oxide is used to replace the titanium dioxide to form the semiconductive layer 14, meaning the same method of forming the photo sensor in the example 2 is used here to obtain a photo sensor having a nickel-zinc oxide core-shell structure.

### Testing Example 1

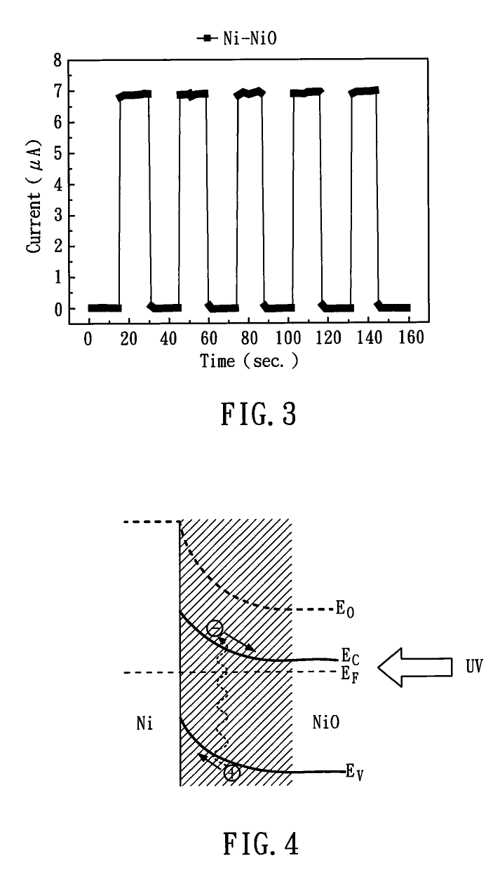

The photo sensor 1 in the example 1 is used for non-power UV detecting test, a time dependent photocurrent response of the photo sensor 1 is monitored with a period of ˜15 seconds. In detail, a UV light source (R-800) for illuminating UV light is turned “on” and “off” alternately for each ˜15 seconds, and a photocurrent response of the photo sensor 1 to the UV light is monitored. As shown in FIG. 3, the result of the photocurrent response of the photo sensor 1 is shown, it can be seen that when the UV light irradiates the nickel-nickel oxide core-shell structure, a current of about 7 μA is outputted immediately, whereas no current is detected while the UV light is turned off. It should be noticed that the dark current is zero because no bias voltage is applied during the whole non-power UV detecting test, which means energy-free (non-power) UV detection is achieved and the requirements for energy-saving criteria is realized by the photo sensor of the present invention.

As well known to those skilled in the art, photo sensors are usually designed to have nanowires with Ohmic contact on both ends/sides. Although a known photo sensor structure comprising nanowires with Schottky contact on one side and Ohmic contact on the other side has been developed, an external bias voltage is needed while such photo sensor is used.

In contrast, the photo sensor of the present invention has a core-shell array structure (metallic nanowire as core, and semiconductive layer as shell) that generates a large-area Schottky contact, and therefore no external bias voltage is needed while the photo sensor is used for photo sensing. The photo sensor of the present invention has a high photosensitivity, and the structure of the one-dimensional nanowire may contribute to confine the carrier transportation direction, whereby the transportation efficiency of the electrical current can be increased. Consequently, the present invention provides a photo sensor structure for photo sensor devices with low power, high sensitivity, and high response speed, which can be used in photo switches for commercial, military, or space exploration applications.

As shown in FIG. 4, an energy band for the interface between the nickel and nickel oxide is shown. It can be seen that a Schottky contact is formed between the nickel and nickel oxide (the core-shell structure of nickel-nickel oxide), which accordingly greatly enhances UV detecting efficiency. As a result, the photo-generated electrons and holes are quickly separated due to the influence by a built-in internal electric field of the Schottky contact, so as to generate photoelectrical current. Consequently, a photo sensor with advantages of low-power consumption and high sensitivity is produced by the present invention, which cannot be obtained by any prior art.

### Testing Example 2

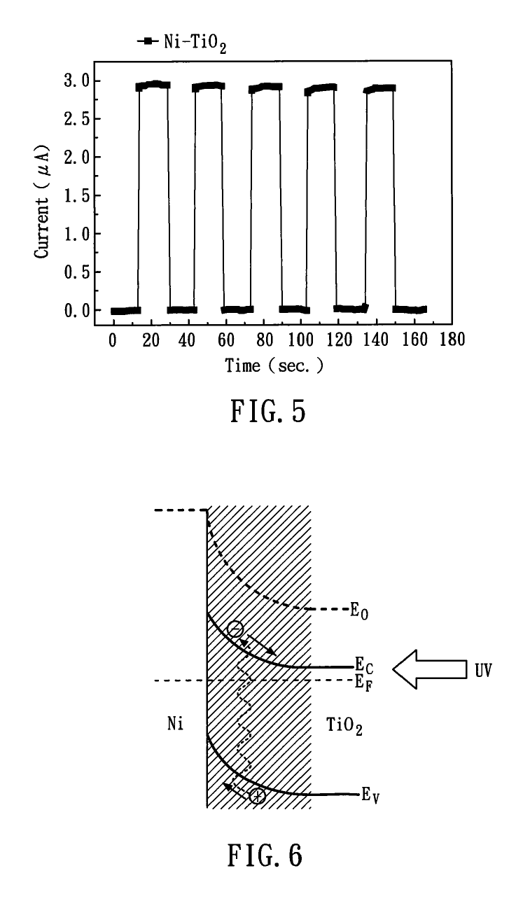

The photo sensor 1 of the example 2 is taken for non-power UV detecting test, a time dependent photocurrent response of the photo sensor 1 is monitored with a period of ˜15 seconds. In detail, a UV light source (R-800) for illuminating UV light is turned “on” and “off” alternately for each ˜15 seconds, and a photocurrent response of the photo sensor 1 to the UV light is monitored. As shown in FIG. 5, the result of the photocurrent response of the photo sensor 1 is shown. It can be seen that when the UV light irradiates the nickel-titanium dioxide core-shell structure, a current of about 3 μA is outputted immediately, whereas no current is detected while the UV light is turned off, which means the dark current is zero.

As shown in FIG. 6, an energy band for the interface between the nickel and titanium dioxide is shown. It can be seen that a large-area Schottky contact is formed between the nickel and titanium dioxide (the core-shell structure of nickel-titanium dioxide), which accordingly greatly enhances UV detecting efficiency. As a result, the photo-generated electrons and holes are quickly separated due to the influence by a built-in internal electric field of the Schottky contact, so as to generate photo-electrical current. As mentioned above, according to the photo sensor structure of a conventional technique, usually both of the connecting points at the opposite sides of the nanowire are Ohmic contacts, which needs bias voltage during operation. Although some studies have proposed a structure in which one Ohmic contact is changed into one Schottky contact, a bias voltage is still needed during the photo sensing.

In contrast, the photo sensor of the present invention has a core-shell array structure that generates an extremely large Schottky contact area, and therefore no external bias voltage is needed (the dark current is zero) while the photo sensor is used for photo sensing. Furthermore, the photo sensor of the present invention has a high sensitivity for UV lights without bias voltage, and the structure of the one-dimensional nanowire may contribute to confine the carrier transportation direction, whereby the transportation efficiency of the electrical current can be increased. Consequently, the present invention provides a photo sensor structure for photo sensor devices with low power, high sensitivity, and high response speed, which can be used in photo switches for commercial, military, or space exploration applications.

Although the present invention has been explained in relation to its preferred embodiment, it is to be understood that many other possible modifications and variations can be made without departing from the spirit and scope of the invention as hereinafter claimed.

What is claimed is:

1. A photo sensor, comprising:
a first conductive layer;
plural metallic nanowires, in which one end of each metallic nanowire connects with the first conductive layer, and each of the metallic nanowires are covered with a semiconductive layer having a thickness of 1 nm to 20 nm; and
a second conductive layer locating opposite to the first conductive layer, whereby the plural metallic nanowires locate between the first conductive layer and the second conductive layer, and the semiconductive layer contacts with the second conductive layer,
wherein the photo sensor is used to detect ultra violet (UV) light with a wavelength of 10 nm to 400 nm.

2. The photo sensor as claimed in claim 1, wherein the plural metallic nanowires are arranged in an array.

3. The photo sensor as claimed in claim 1, wherein the plural metallic nanowires are arranged vertically to the first conductive layer.

4. The photo sensor as claimed in claim 1, wherein the metallic nanowires and the semiconductive layer together form a core-shell structure.

5. The photo sensor as claimed in claim 1, wherein a Schottky contact is formed by the contact between the metallic nanowires and the semiconductive layer.

6. The photo sensor as claimed in claim 1, wherein the metallic nanowires have an average diameter of 60 nm to 70 nm.

7. The photo sensor as claimed in claim 1, wherein the metallic nanowires are made of nickel, zinc, or mixtures thereof.

8. The photo sensor as claimed in claim 1, wherein the semiconductive layer is made of nickel oxide, zinc oxide, titanium oxide, or mixtures thereof.

9. The photo sensor as claimed in claim 1, wherein the second conductive layer is made of: indium tin oxide (ITO), aluminum doped zinc oxide (AZO), indium zinc oxide (IZO), or mixtures thereof.

10. A method of providing a photo sensor, comprising:
(A) providing a substrate;
(B) forming a first conductive layer on the substrate;
(C) forming plural metallic nanowires on the first conductive layer, in which one end of each metallic nanowire connects with the first conductive layer;
(D) forming a semiconductive layer covering each of the metallic nanowires, in which the thickness of the semiconductive layer is 1 nm to 20 nm; and
(E) forming a second conductive layer contacting with the semiconductive layer, in which the plural metallic nanowires locate between the first conductive layer and the second conductive layer;
wherein the photo sensor is used to detect ultra violet (UV) light with a wavelength of 10 nm to 400 nm.

11. The method of providing a photo sensor as claimed in claim 10, wherein in the step (C), the plural metallic nanowires are formed by steps (C1): forming an aluminum anode oxide (AAO) layer comprising plural holes on the first conductive layer; (C2) forming metallic nanowires in the holes of the AAO layer; and (C3) removing the AAO layer.

12. The method of providing a photo sensor as claimed in claim 11, wherein in the step (C2), the metallic nanowires are formed in the holes of the AAO layer by electroplating or electroless plating.

13. The method of providing a photo sensor as claimed in claim 10, wherein in the step (D), the semiconductive layer is formed by a step (D1): annealing the plural metallic nanowires to form a metal oxide-semiconductive layer on the metallic nanowires.

14. The method of providing a photo sensor as claimed in claim 13, wherein in the step (D1), the time for the annealing is 10 minutes to 120 minutes.

15. The method of providing a photo sensor as claimed in claim 13, wherein in the step (D1), the temperature for the annealing is 250° C. to 450° C.

16. The method of providing a photo sensor as claimed in claim 10, wherein in the step (D), the semiconductive layer is formed by a step (D2): forming the semiconductive layer on each of the metallic nanowires by an atomic layer deposition (ALD) method.

17. The method of providing a photo sensor as claimed in claim 10, wherein in the step (D), the substrate is selected from the group consisted of: a silicon substrate, a glass substrate, a quartz substrate, a metallic substrate, a plastic substrate, a printed circuit board, and mixtures thereof.

18. The method of providing a photo sensor as claimed in claim 10, wherein a Schottky contact is formed by the contact between the metallic nanowire and the semiconductive layer.
